(19) United States
(12) Patent Application Publication
(10) Pub. No.: US 2009/0133902 A1
(43) Pub. Date: May 28, 2009

(54) Printed circuit board

(75) Inventors: Chin-Kwan Kim, Yuseong-gu (KR); Tae-Gon Lee, Seo-gu (KR); Young-Mi Lee, Daedeok-gu (KR); Yoon-Hee Kim, Wonju-si (KR); Hwa-Jun Jung, Cheongju-si (KR); Kui-Won Kang, Icheon-si (KR); Yong-Bin Lee, Cheongju-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/292,853

(22) Filed: Nov. 26, 2008

(30) Foreign Application Priority Data
Nov. 27, 2007 (KR) 10-2007-0121700

(51) Int. Cl. H05K 1/00

(52) U.S. Cl. 174/250

(57) ABSTRACT

A printed circuit board is disclosed. The printed circuit board, which may include an insulation layer, a first metal pad formed on the insulation layer, a second metal pad electrically coupled with the first metal pad and having an ionization tendency lower than that of the first metal pad, and a sacrificial electrode electrically coupled with the second metal pad to prevent corrosion in the first metal pad, can be utilized to prevent excessive etching that may otherwise occur due to galvanic corrosion between metal pads of different ionization tendencies.

### CROSS-REFERENCE TO RELATED APPLICATIONS

This application claims the benefit of Korean Patent Application No. 10-2007-0121700 filed with the Korean Intellectual Property Office on Nov. 27, 2007, the disclosure of which is incorporated herein by reference in its entirety.

### BACKGROUND

1. Technical Field

The present invention relates to a printed circuit board.

2. Description of the Related Art

A semiconductor package board allows the mounting of electronic components on the surface, and in certain cases, such as for a BGA (ball grid array) board, provides electrical connection to other package boards. Here, to provide electrical connection to components or to other package boards, wire bonding pads or solder ball pads, etc., may be used.

FIG. 1 is a plan view of a board strip according to the related art, and FIG. 2 is a plan view of a unit board according to the related art. As illustrated in FIG. 1, a board strip 100 may include a unit zone 120, in which unit boards 130 may be formed, and a zone outside the unit zone 120, i.e. a dummy zone 110, in which mold gates 112 may be formed. Also, the board strip 100 may ultimately be cut along the product zone 140 of each unit board 130 to be provided as the final product.

As illustrated in FIG. 2, solder ball pads, wire bonding pads, etc., may be formed on a semiconductor package board, to provide electrical connection with the exterior. A solder ball pad may entail an OSP (organic solderability preservative) treatment for preventing the copper (Cu) from oxidizing and increasing the adhesion of the solder ball, while a wire boding pad may entail a gold plating treatment using gold (Au) and nickel (Ni). Plating bars 136 may be connected with the gold plating pads 132 for the gold plating.

An OSP pad 134, e.g. a solder ball pad, may be electrically connected with a gold plating pad, e.g. a wire bonding pad. However, due to the difference in ionization tendency between copper and gold, in the OSP pad 134 and gold plating pad 132, galvanic corrosion may occur in an acidic compound. This may result in an excessive etching of the OSP pad 134, whereby the thickness or width of the OSP pad 134 may be significantly decreased.

This problem can be exacerbated as the difference in area between the OSP pad 134 and the gold plating pad 132 is increased. Forming the OSP pad 134 in larger sizes to resolve this problem may pose difficulties in increasing the density of the wiring.

### SUMMARY

One aspect of the invention provides a printed circuit board, in which excessive etching caused by galvanic corrosion between metal pads of different ionization tendencies can be prevented, when applying an OSP (organic solderability preservative) pretreatment.

Another aspect of the invention provides a printed circuit board that includes an insulation layer, a first metal pad formed on the insulation layer, a second metal pad electrically coupled with the first metal pad and having an ionization tendency lower than that of the first metal pad, and a sacrificial electrode electrically coupled with the second metal pad to prevent corrosion in the first metal pad.

Here, the insulation layer can be partitioned into a unit zone, in which multiple unit boards may be formed, and a dummy zone. The sacrificial electrode can be formed in the dummy zone, or on a unit board. Also, the sacrificial electrode may contain the same metal as that of the first metal pad.

The first metal pad contains copper (Cu), while the second metal pad may contain gold (Au). Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a plan view of a board strip according to the related art.

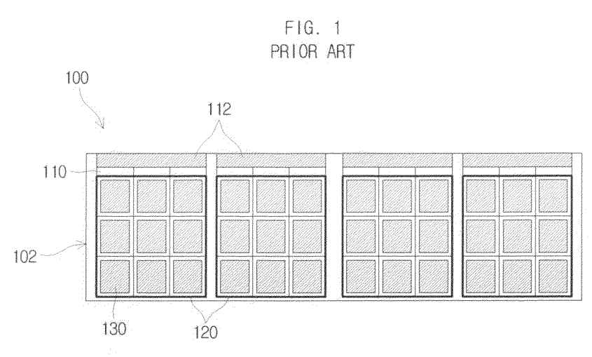

FIG. 2 is a plan view of a unit board according to the related art.

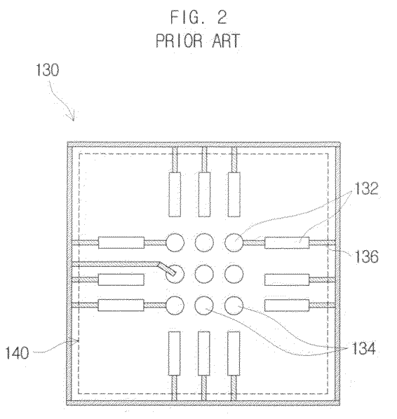

FIG. 3 is a plan view of a portion of a board strip according to a first disclosed embodiment of the invention.

FIG. 4 is a plan view of a portion of a board strip according to a second disclosed embodiment of the invention.

FIG. 5 is a plan view of a portion of a board strip according to a third disclosed embodiment of the invention.

### DETAILED DESCRIPTION

Before describing particular embodiments of the invention, a description will be provided on OSP (organic solderability preservative) treatment as follows. For example, in the case of a solder ball pad, OSP treatment may be applied in order to prevent oxidation in the copper and to improve adhesion to solder balls. OSP treatment is a method of forming a protective film by displacing the copper in a pad or a hole with an organic compound, such as imidazole, benzotriazole, benzimidazole, etc. An example of a well known type of OSP treatment is the water-soluble pre-flux method.

When applying an OSP treatment, a pad containing copper and a pad containing gold may be exposed to an acidic compound, at which galvanic corrosion may occur.

Galvanic corrosion is caused by a difference in electrode potentials, when two dissimilar metals are placed in an electrolyte solution, which causes electrons to move from one metal to the other. Because of this, the corrosion of the metal having the lower ionization tendency is retarded, while the corrosion of the metal having higher ionization tendency is accelerated. This type of corrosion is referred to as galvanic corrosion or dissimilar metal corrosion.

An important factor affecting galvanic corrosion is the proportion of the area of the anode to the area of the cathode. The more risky situation may involve a set of small anode and large cathode. The higher the current density in an anode, the greater is the rate of corrosion. Conversely, a set of large anode and small cathode may be more favorable in preventing galvanic corrosion. For example, consider the cases of a steel nail hammered into a copper plate and a copper nail hammered into a steel plate. The former case is an example of a set of small anode and large cathode, while the latter case is an example of a set of large anode and small cathode. Therefore, compared to the latter case, the galvanic corrosion in the former case will be much more serious, and the steel nail will be subject to a considerable amount of damage.

As described above, a printed circuit board according to a first disclosed embodiment of the invention may include an insulation layer, a first metal pad formed on the insulation layer, a second metal pad electrically coupled with the first metal pad and having an ionization tendency lower than that of the first metal pad, and a sacrificial electrode electrically coupled with the second metal pad to prevent corrosion in the first metal pad, whereby excessive etching, which may occur due to galvanic corrosion caused by metal pads having different ionization tendencies contacting an etching compound, can be avoided.

A printed circuit board according to a certain embodiments of the invention will now be described in more detail, with reference to the accompanying drawings. Those components that are the same or are in correspondence are rendered the same reference numeral regardless of the figure number, and redundant explanations are omitted.

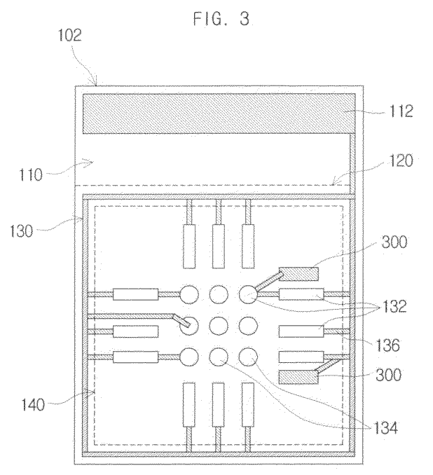

FIG. 3 is a plan view of a portion of a board strip according to the first disclosed embodiment of the invention. In FIG. 3, there are illustrated a board strip 100, an insulation layer 102, a dummy zone 110, a mold gate 112, a unit zone 120, a unit board 130, gold plating pads 132, OSP pads 134, plating bars 136, a product zone 140, and sacrificial electrodes 300, etc.

A printed circuit board is an arrangement that includes an insulation layer 102 and a conductive layer formed in a particular pattern over the insulation layer 102. The printed circuit board may refer to a board strip 100, which is an intermediary product in the manufacturing process, or may refer to a unit board 130, which is a partitioned portion of a board strip 100 that is to be ultimately cut as a final product. It is to be appreciated that the board strip 100 and the unit board 130 are both labels signifying the form of the product with respect to the manufacturing process, and that both of these may be referred to as a printed circuit board. Moreover, it is apparent that the portion ultimately cut along the product zone 140 is also referred to as a printed circuit board.

When the printed circuit board is in the form of a board strip 100, the insulation layer 102 may be partitioned into a unit zone 120, in which multiple unit boards 130 may be formed, and a dummy zone 110, which is a zone outside the unit zone 120. The dummy zone 110 may include guide holes for aligning the board strip 100 or mold gates 112, etc.

The first disclosed embodiment of the invention will be described for an example case as applied to a unit board 130, which is a form of printed circuit board.

As illustrated in FIG. 3, the printed circuit board may include a circuit pattern (not shown) on an insulation layer 102, and pads, etc., that provide electrical connection between the circuit pattern and the exterior. The pads may be divided into gold plating pads 132, in which a gold plating layer may be formed, and OSP pads 134, in which OSP treatment may be applied. Plating bars 136 may be coupled with the gold plating pad 132 to supply electrical power for the gold plating.

The gold plating pads 132 can be electrically coupled with the OSP pads 134 by the circuit pattern. The OSP pads 134 can be formed on a portion of the circuit pattern, and can include, for example, copper (Cu). Gold (Au) is a metal having a lower ionization tendency than that of copper. Thus, because copper and gold, which have different ionization tendencies, may be electrically coupled, galvanic corrosion may occur in the OSP pads 134 when the two types of metallic pads are exposed to an acidic compound during the OSP pretreatment.

Therefore, in order to prevent galvanic corrosion in the OSP pads 134, sacrificial electrodes 300 may be coupled electrically to the gold plating pads 132. The sacrificial electrodes 300 may include, for example, copper. By coupling the sacrificial electrodes 300 made of the same metal as that used in the OSP pads 134 to the gold plating pads 132, the proportion of the area of the anode between the metals of the OSP pads 134 and gold plating pads 132 can be increased. The sacrificial electrodes 300 can be formed together with the circuit pattern during the operation of forming the circuit pattern.

While this particular embodiment employs a method of using sacrificial electrodes 300 having the same metal (e.g. copper) as that of the OSP pads 134 to increase the proportion of the anode area between the metals used and thereby prevent galvanic corrosion in the OSP pads 134, it is also possible to reduce the occurrence of galvanic corrosion by forming the sacrificial electrodes 300 from a metal having a higher ionization tendency than that of the metal forming the OSP pads 134.

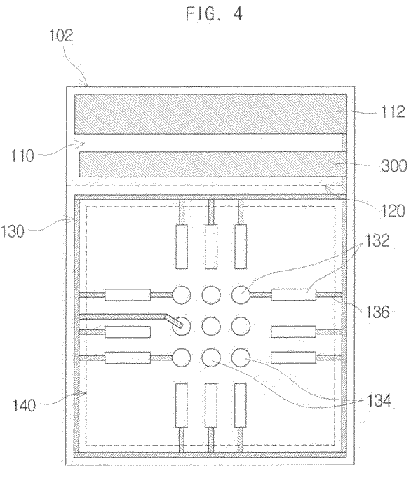

FIG. 4 is a plan view of a portion of a board strip 100 according to a second disclosed embodiment of the invention. The printed circuit board according to the second disclosed embodiment of the invention may have the form of a board strip 100. The printed circuit board is described for an example case in which the sacrificial electrodes 300 are formed in the dummy zone 110.

As illustrated in FIG. 4, a sacrificial electrode 300 can be electrically connected with the gold plating pads 132 by way of the plating bars 136, and can be formed in the dummy zone 110. Gold plating layers may be formed over the plating bars 136 and the mold gate 112. The OSP pads 134 may contain copper, while the sacrificial electrode 300 may also contain copper. The sacrificial electrode 300, made of the same metal as that of the OSP pads 134, can be formed in the dummy zone 110, to increase the proportion of the anode area between the metals of the OSP pads 134 and gold plating pads 132, and thereby reduce the occurrence of galvanic corrosion between the metals that may occur during the OSP pretreatment.

As a result, by forming the sacrificial electrode 300, not in the unit board 130 which is yielded as the final product, but in the dummy zone 110, problems caused by galvanic corrosion can be resolved, while providing a high wiring density.

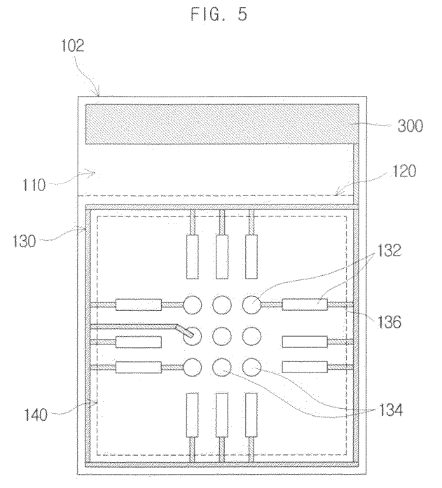

FIG. 5 is a plan view of a portion of a board strip 100 according to a third disclosed embodiment of the invention. In the printed circuit board according to the third disclosed embodiment of the invention may have the form of a board strip 100. In this example case, gold plating is not performed over the mold gate formed in the dummy zone 110, so that the mold gate may be used as the sacrificial electrode 300.

The mold gate may be formed on one side of the board strip 100, and gold plating may be performed over the mold gate, in order to facilitate the inflow of epoxy molding resin as well as its subsequent separation. However, with recent improvements in epoxy molding resin, the gold plating for the mold gate can be omitted. As such, the surface of the mold gate may include copper, which can be used as the sacrificial electrode 300, instead of forming a separate sacrificial electrode 300.

In this particular embodiment also, the mold gate containing copper may serve as the sacrificial electrode 300, to increase the proportion of the anode area with respect to the gold plating pads 132 and reduce galvanic corrosion that may occur during the OSP pretreatment. Also, by forming the sacrificial electrode 300 in the dummy zone 110, galvanic corrosion may be prevented without having to form the OSP pads 134 in excessively large sizes, so that the wiring densities of the unit boards 130 may be improved.

As set forth above, certain embodiments of the invention can be utilized to prevent excessive etching that may otherwise occur due to galvanic corrosion between metal pads of different ionization tendencies.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board comprising:
an insulation layer;
a first metal pad formed on the insulation layer;
a second metal pad electrically coupled with the first metal pad and having an ionization tendency lower than that of the first metal pad; and
a sacrificial electrode electrically coupled with the second metal pad such that the first metal pad is prevented from corroding.

2. The printed circuit board of claim 1, wherein the insulation layer is partitioned into a unit zone and a dummy zone, the unit zone having a plurality of unit boards formed therein.

3. The printed circuit board of claim 2, wherein the sacrificial electrode is formed in the dummy zone.

4. The printed circuit board of claim 2, wherein the sacrificial electrode is formed on the unit board.

5. The printed circuit board of claim 1, wherein the sacrificial electrode contains a same metal as that of the first metal pad.

6. The printed circuit board of claim 1, wherein the first metal pad contains copper (Cu).

7. The printed circuit board of claim 6, wherein the second metal pad contains gold (Au).
